(19) United States
(12) Patent Application Publication
(10) Pub. No.: US 2003/0067357 A1
(43) Pub. Date: Apr. 10, 2003

(54) Automatic multiple II/4 phase shifter

(76) Inventors: Hung Chang Lin, Silver Spring, MD (US); Ming-Hao Sun, Rockville, MD (US)

Correspondence Address: Hung Chang Lin, 8 Schindler Court, Silver Spring, MD, 20903, US

(21) Appl. No.: 10/227,658

(22) Filed: Aug. 26, 2002

Related U.S. Application Data
(60) Provisional application No. 60/327,256, filed on Oct. 5, 2001.

(51) Int. Cl. H03L 7/00

(52) U.S. Cl. 331/17

(57) ABSTRACT

An ac input voltage is fed to one input of a multiplier serving phase comparator of a phase-locked loop. The output voltage of the VCO feeding the second input of the phase comparator to lock the frequency has a π/4 phase shift with respect to the input voltage. When two such phase locked loops are connected in tandem, a π/2 quadrature voltage is obtained. When more than two phase-locked loops are connected in tandem, any multiples of π/4 phase shift can be obtained.

### BACKGROUND OF THE INVENTION

(1) Field of the Invention

The invention relates to wireless communication circuits, particularly to the modulation and demodulation of communication circuits.

(2) Brief Description of Related Art

In present day wireless communication, selectivity is important to reject unwanted signals and noise. The superheterodyne radio receiver has been widely used for good selectivity by beating the incoming signal with a local oscillator to generate fixed intermediate frequency (IF) which can be sharply filtered to reject unwanted signals. Unfortunately, the superheterodyne design suffers from the image problem, in that an undesired image frequency can also beat with the local oscillator to generate the same intermediate frequency.

Various schemes have been developed to overcome the image problem. Among them are the single side-band filter as shown in FIGS. 1(a) and (b); zero-intermediate frequency as shown in FIG. 1(d), etc. In many of these approaches such as the balanced modulator shown in FIG. 1(b) or the zero-IF shown in FIG. 1(d), two frequencies at 90° phase difference (in quadrature) are used.

In the detection of a frequency modulated (FM) a quadrature detector as shown in FIG. 1(d) is widely used. For such a circuit, the input signal must be split into quadrature signals.

In most of these circuits, the quadrature signals are derived from the phase shifter comprising R-C networks. FIG. 2(a) shows a quadrature generator for a single frequency using an R-C bridge. Although the output V_{I} and output V_{Q} are in quadrature, the amplitudes are equal only at one frequency. For a broadband generator, a more complicated R-C network such as that shown in FIG. 2(b) have been used, but the relative quadrature voltages still vary with frequency. FIG. 2(c) shows a digital quadrature generator, which can generate only equal quadrature voltages but not other multiples of π/4 (45°) phase shifts. The higher frequency capability is also limited.

### SUMMARY OF THE INVENTION

An object of this invention is to generate a broadband quadrature phase shift automatically. Another object of this invention is to generate multiples of π/4 phase shift automatically. Still another object of this invention is to generate broadband quadrature voltages with constant amplitude.

These objects are achieved by using more than one a phase-locked loop. The frequency fed back from the voltage-controlled oscillator (VCO) to the phase comparator has a phase shift of 45° (π/4) from the input signal. By using two phase-locked loops in tandem, a quadrature (π/2) signals can be obtained.

### BRIEF DESCRIPTION OF THE DRAWINGS

FIG. 1(a) shows a single-side band generator using a sideband filter; FIG. 1(b) shows a balanced modulator for single sideband generation; FIG. 1(c) shows a wideband FM genertor; FIG. 1(d) shows a mixer for generating a generating a in-phase signal and a quadrature signal in a zero IF receiver; FIG. 1(e) shows a quadrature FM demodulator.

FIG. 2(a) shows a analog passive analog quadrature generator; FIG. 2(b) shows a broadband quadrature generator; FIG. 2(c) shows a digital quadrature generator.

FIG. 3(a) shows a phase-locked loop for generating a π/4 phase shift based on the present invention; FIG. 3(b) shows a Gilbert multiplier for the phase comparator of the phase-locked loop; FIG. 3(c) shows a Exclusive-OR as a phase comparator.

FIG. 4 shows a block diagram for generating quadrature phase shift.

FIG. 5 shows a block diagram for generating multiple π/4 phase shift.

FIG. 6 shows a second embodiment of the present invention.

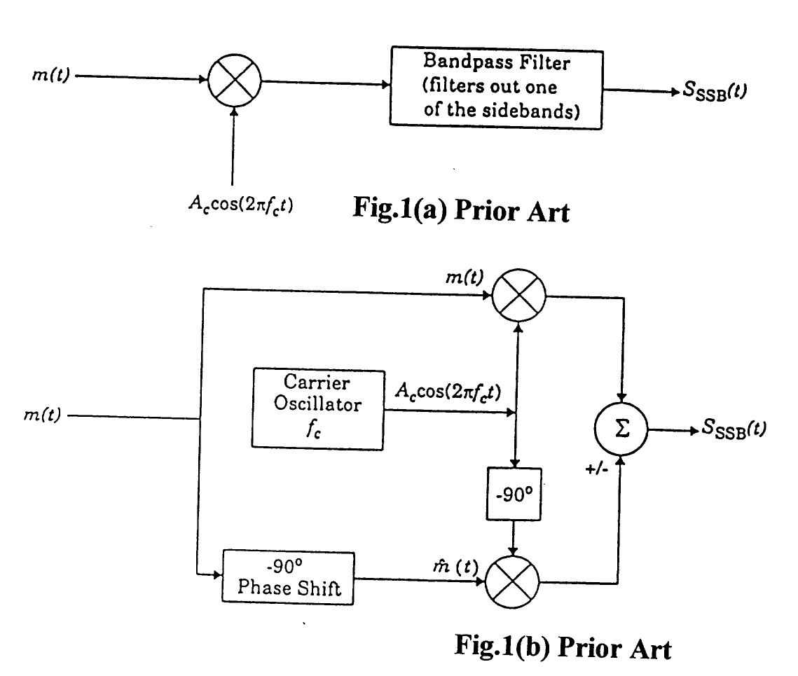

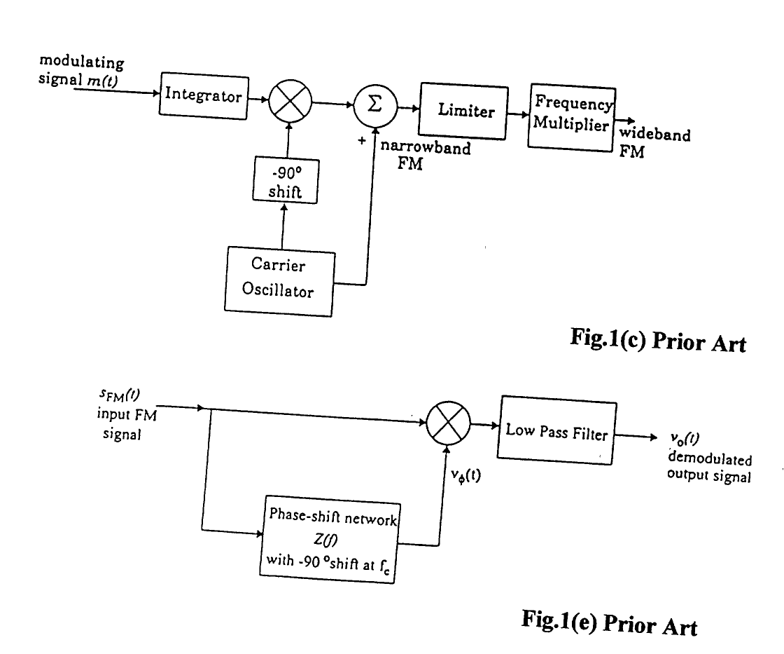

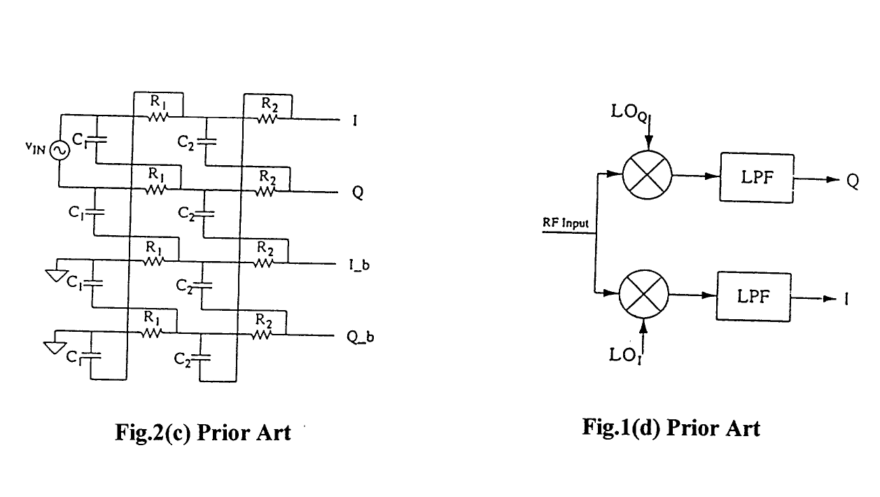

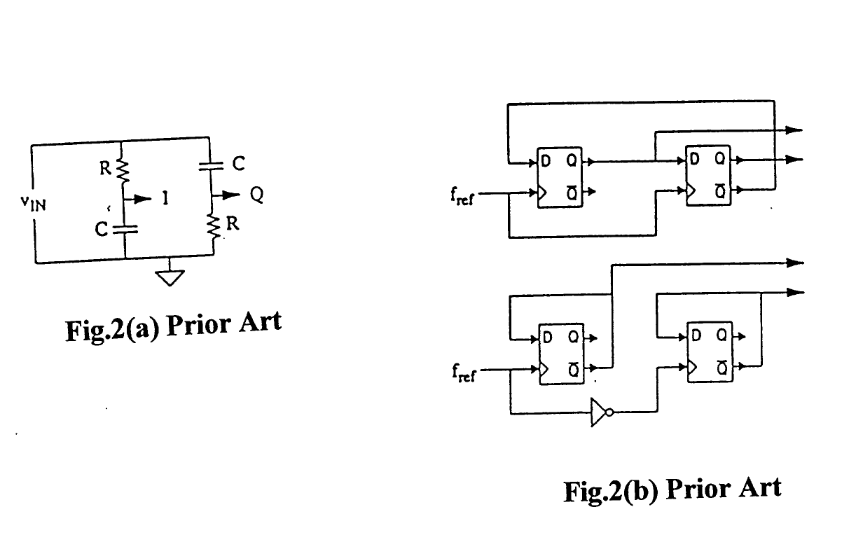

### DETAILED DESCRIPTION OF THE INVENTION

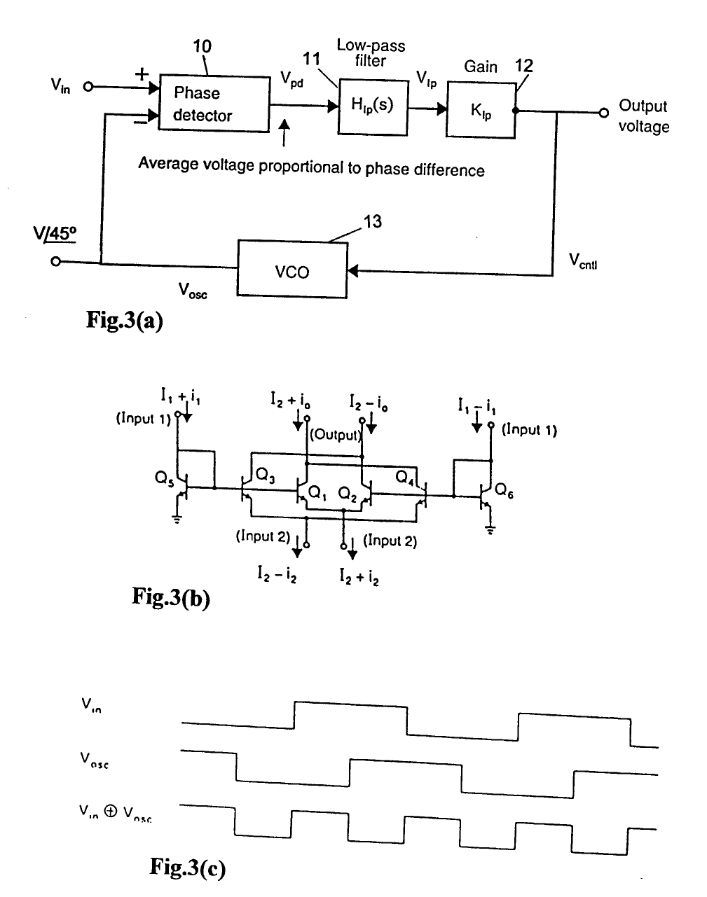

FIG. 3(a) shows the basic building block of the present invention. The circuit is a phase-locked loop. An input voltage Vin is applied to a phase comparator 10 to produce a phase difference voltage Vpd, which is filtered by a low-pass filter 11 to remove the ac components and to obtain a dc voltage Vlp, which may be amplified by an optional amplifier 12 to yield a control voltage Vcntl. This control voltage Vcntl is used to control the frequency of a voltage controlled oscillator (VCO) 13. The frequency of the output voltage Vosc is compared with the incoming frequency in the phase comparator 10. Then the frequency of the VCO is locked with the incoming signal Vin frequency. When a multiplier is used as the phase comparator 10, the phase of the VCO output voltage Vosc is shifted by 45° or π/4, i.e. Vosc∝Vin∠45° The multiplier may be a Gilbert multiplier as shown in FIG. 3(b) or an Exclusive OR logic gate as shown in FIG. 3(c). Thus a π/4 phase shifter is obtained. The phase shifting is automatic over a wide range of frequency. The different types of VCO may be used, such as relaxation oscillators, ring oscillators, LC oscillators, etc. Unlike the passive RC phase shifters, most oscillators have reasonably uniform output voltages over a wide frequency range, especially the relaxation oscillators.

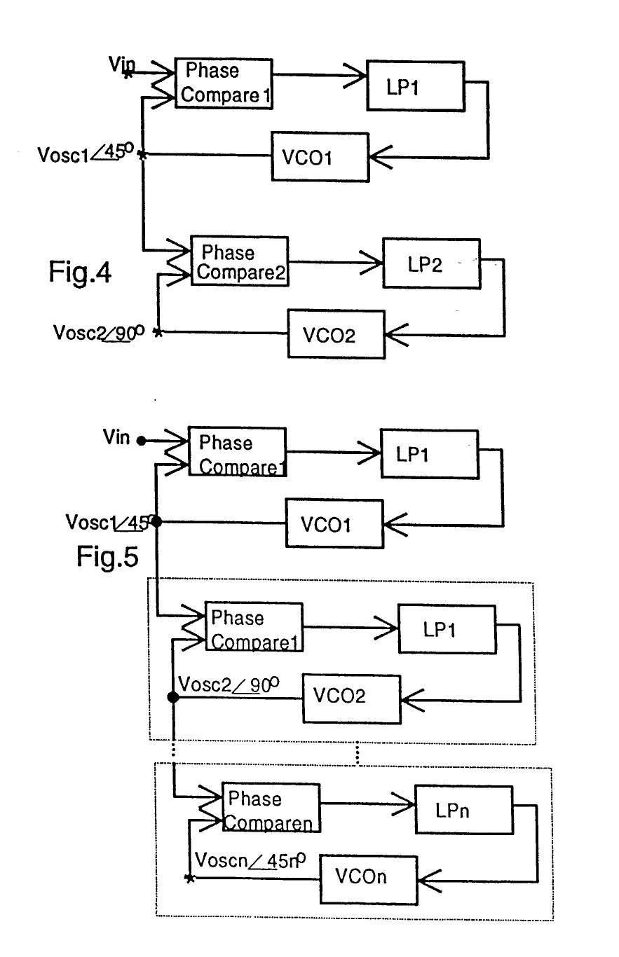

When two π/4 phase shifters are connected in tandem as shown in FIG. 4, the phase shift is doubled to be π/2 or 90°. The output voltage Vosc₂ of the second VCO₂ is phase shifted by π/4 from the first voltage controlled oscillator output Vosc₁ and therefore phase shifted by π/2 or in quadrature with the input signal Vin.

In the same manner, more than two phase locked loops may be used to generate multiple π/4 phase shift, as shown in FIG. 5. When N phase locked loops are used, the phase shift is equal to Nπ/4.

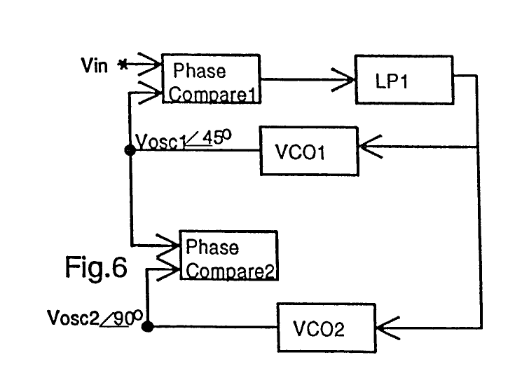

In FIG. 4, the control voltage Vcntl₁ for the first VCO₁ is separate from the control voltage Vcntl₂ for the second VCO₂. If the VCO₁ and VCO₂ are identical, then the control voltage Vcntl₁ for VCO₁ and the control voltage Vcntl₂ are the same. Then the same control voltage Vcntl can be applied to both VCO₁ and VCO₂ and only one phase comparator is needed as shown in FIG. 6.

While the phase comparators are shown FIG. 3(b) and FIG. 3(c) as Gilbert multiplier and an Exclusive-OR, the phase comparator is not limited to these two types so long the locked frequency of the VCO has aπ/4 phase shift with respect to the input frequency.

1. An automatic phase shift generator, comprising:
an ac input voltage of a first frequency;
an phase comparator having one input fed from said ac input voltage;
a first voltage-controlled oscillator (VCO) generating an oscillating frequency controlled by a controlled voltage filtered from the output of said phase comparator;
an output voltage from said first VCO fed to a second input of said phase comparator to form a phase-locked loop; and serving as aπ/4 phase-shifted voltage of said input voltage.

2. An automatic phase shift generator as described in claim 1, wherein said phase comparator is an analog multiplier.

3. An automatic phase shift generator as described in claim 2, wherein analog multiplier is a Gilbert multiplier.

4. An automatic phase shift generator as described in claim 1, wherein said phase comparator is an Exclusive-OR gate.

5. An automatic phase shift generator as described in claim 1, further comprising a second phase locked loop having a second phase comparator with one input fed from the output of said first VCO, and a second VCO having a second VCO output voltage fed to the second input of said second phase comparator to yield a π/2 quadrature voltage with respect to said input voltage.

6. An automatic phase shift generator as described in claim 1, further comprising more than two phase locked loops in tandem each having a dedicated phase comparator with one input fed from the output of a previous VCO, and a VCO having an output voltage fed to the second input of said dedicated phase comparator to yeild a Nπ/4 phase shift with respect to the input voltage, where N is an integer number.

7. An automatic phase shift generator as described in claim 6, wherein a single phase comparator is used to yield a common control voltage for each dedicated VCO.
